(19) United States
(12) Patent Application Publication
(10) Pub. No.: US 2020/0166595 A1
(43) Pub. Date: May 28, 2020

(54) METHOD FOR CONTROLLING A MAGNETIC RESONANCE TOMOGRAPHY SYSTEM

(71) Applicant: Siemens Healthcare GmbH, Erlangen (DE)

(72) Inventors: Dominik Paul, Bubenreuth (DE); Flavio Carinci, Wuerenlingen (CH); Mario Zeller, Erlangen (DE)

(73) Assignee: Siemens Healthcare GmbH, Erlangen (DE)

(21) Appl. No.: 16/695,269

(22) Filed: Nov. 26, 2019

(30) Foreign Application Priority Data
Nov. 27, 2018 (DE) 102018220353.9

(51) Int. Cl. G01R 33/54; G01R 33/483; G01R 33/48

(52) U.S. Cl. CPC G01R 33/543; G01R 33/4828; G01R 33/4835

(57) ABSTRACT

A method and apparatus for controlling a magnetic resonance tomography system in context of a multi-echo imaging method, the method including exciting a multi-echo readout in the context of the multi-echo imaging method, and varying a phase encoding or slice encoding of temporally successive echoes of an echo train resulting from the multi-echo readout.

### TECHNICAL FIELD

The disclosure describes a method for controlling a magnetic resonance tomography system in the context of a multi-echo imaging method, a corresponding multi-echo sequence, an apparatus for producing such a multi-echo sequence, a control device for a magnetic resonance tomography system, and a magnetic resonance tomography system.

### BACKGROUND

In the context of certain imaging methods using magnetic resonance tomography systems (MRT systems), scans are carried out with multiple readout windows. Acquisition sequences for such scans are typically referred to as multi-echo sequences.

In multi-echo sequences (such as MEDIC (“Multi-Echo Data Image Combination”), DESS (“Dual-Echo Steady-State”), etc.) as well as in (multi-echo-)DIXON methods, multiple echoes are acquired for each k-space line and later combined to form one or more images.

The echo train for a MEDIC sequence is shown by way of example in FIG. 3. Here, one complete “echo train” with multiple echoes with a different echo time TE is recorded for each phase encoding step. Single images with a different echo time are reconstructed in each case from the single echoes and are subsequently combined by means of a MEDIC image computation to form one MEDIC image.

Methods exist for accelerating the scan, such as GRAPPA or SENSE. These are used to shorten the imaging times.

The disadvantage of these multi-echo sequences is that the scan time, especially for execution as a 3D variant, is very long even if the actual echo imaging can be performed in a highly compressed manner. Imaging times of 5 mins and longer are quite normal even if the known acceleration methods are used.

### SUMMARY

An object of the present disclosure is to provide a method for controlling a magnetic resonance tomography system with which a shortening of the scan time can be achieved, and in particular the risk of movement artifacts is additionally suppressed.

The starting point in what follows are sequences that are designed to produce multiple echoes within one phase encoding step. These sequences are referred to here as “multi-echo sequences”. This designation is independent of the manner in which the scan results are used. By way of example, sequences for the imaging of data for a DIXON method are also referred to here as “multi-echo sequences”.

A method according to the disclosure for controlling a magnetic resonance tomography system in the context of a multi-echo imaging method could also be referred to as a “magnetic resonance tomography imaging method” and serves in particular to generate multiple echoes within a phase encoding step in the context of a scan using a magnetic resonance tomography system. The method comprises the following steps:

Excitation of a multi-echo readout in the context of the multi-echo imaging method. This excitation is essentially known to the person skilled in the art. Typically this excitation of a multi-echo readout occurs in the context of the multi-echo imaging method by means of a multi-echo sequence. Because this multi-echo sequence is crucial for the multi-echo imaging method, theoretically the two terms can also be used synonymously. However, the term “imaging method” indicates somewhat more clearly how the multi-echo sequence is applied, whereas the term “multi-echo sequence” tends to describe more clearly the temporal and spatial arrangement of different signals. Therefore, both terms are used in what follows.

Variation of a phase encoding and/or slice encoding of a number of temporally successive echoes of an echo train resulting from the multi-echo readout (i.e. within one phase encoding step). Although a variation of only the slice encoding could take place, the focus in many preferred applications is on the phase encoding. A variation of the phase encoding or a variation of the phase encoding and the slice encoding is therefore preferred in these applications.

This specific variant of compressed sensing further reduces the scan time for a magnetic resonance tomography scan, wherein the variation allows the sparsity between the single echoes to be used. Compared with conventional acceleration methods, in the context of the disclosure, the phase encoding and/or the slice encoding is varied between each of the echoes.

One advantage of the disclosure is therefore a combination of compressed sensing and sparse sampling. This can be applied to multi-echo methods such as MEDIC, DESS or DIXON. The method according to the disclosure leads to a significant reduction in imaging time TA, and to robustness in respect of movement artifacts.

A multi-echo sequence according to the disclosure for controlling a magnetic resonance tomography system designed for the excitation of a multi-echo readout in the context of a multi-echo imaging method comprises a number of variation gradients. These variation gradients are designed for the variation of a phase encoding and/or slice encoding of a number of temporally successive echoes of an echo train resulting from the multi-echo readout. The variation gradients are therefore arranged temporally in the multi-echo sequence such that they produce a variation of a phase encoding/slice encoding of a number of temporally successive echoes (within one phase encoding step) of an echo train resulting from the multi-echo readout.

In this case the variation gradients are positioned temporally such that they occur before the readout in each case. With regard to the ADC (analog-to-digital converter) signals that control the readout of the ADCs of the magnetic resonance tomography system (also referred to as the “ADC window”), the variation gradients always occur before the ADC signals in each case.

An apparatus according to the disclosure for generating a multi-echo sequence according to the disclosure comprises the following components:

A data interface designed for receiving an examination request in the context of a multi-echo imaging method,

A production unit designed for production or provision of a preliminary multi-echo sequence as a function of the examination request,

A modification unit designed for modification of the preliminary multi-echo sequence by the insertion of variation gradients designed for variation of a phase encoding and/or slice encoding of a number of temporally successive echoes of an echo train resulting from the multi-echo readout, in other words upon application of the multi-echo sequence,

A data interface designed for transmitting the modified multi-echo sequence so that it can be used to control a magnetic resonance tomography system.

A preliminary multi-echo sequence is a multi-echo sequence according to convention that includes no variation gradients within the echo train. This preliminary multi-echo sequence could also be referred to as a “conventional multi-echo sequence”.

A control device according to the disclosure for controlling a magnetic resonance tomography system is designed to perform a method according to the disclosure and/or comprises an apparatus according to the disclosure.

A magnetic resonance tomography system according to the disclosure comprises a control device according to the disclosure.

Most of the aforementioned components, in particular the control device or the apparatus, can be implemented in full or in part in the form of software modules in a processor of a suitable control device or of a processing system. An implementation largely in software has the advantage that even control devices and/or processing systems already in use can be easily upgraded by a software update in order to work in the manner according to the disclosure. In this respect, the object is also achieved by a corresponding computer program product comprising a computer program, which can be loaded directly into a memory device of a control device and/or of a processing system and which contains program segments, in order to perform all the steps of the methods according to the disclosure when the program is executed. Such a computer program product can comprise, where relevant, in addition to the computer program, further components, such as, for example, documentation and/or additional components including hardware components, for example, hardware keys (dongles, etc.) in order to use the software.

For transfer to the control device and/or to the processing system, and/or for storage on, or in, the control device and/or the processing system, a computer-readable medium, for instance a memory stick, a hard disk or any other portable or permanently installed data storage medium can be used, on which are stored the program segments of the computer program, which program segments can be downloaded and executed by a processing unit. For this purpose, the processing unit can comprise, for example, one or more interacting microprocessors or the like.

Further, particularly advantageous embodiments and developments of the disclosure are given in the dependent claims and in the following description, where the claims in one category of claims can also be developed in a similar way to the claims and passages of the description in another category of claims, and in particular individual features of different exemplary embodiments or variants can also be combined to create new exemplary embodiments or variants. In particular, the control device or the apparatus according to the disclosure can also be developed in a similar way to the dependent method claims or passages of the description.

A preferred method comprises the following additional steps:

Provision of an examination request in the context of a multi-echo imaging method. Here, this examination request comprises information indicating the use of a certain multi-echo sequence. In this step, the method is “told” which body region is involved, e.g. which bone or which organ, and which type of imaging is to be performed. By way of example, the examination request may simply comprise an indication of the body region, e.g. “knee AP”, “knee lateral”.

In addition, or as an alternative to the examination request, an organ program can also be provided that comprises an examination request. The organ program is called e.g. knee AP but includes all the parameters necessary for a specific X-ray recording, e.g. information about the generator, image processing, image representation and/or equipment position.

Provision of a multi-echo sequence from a data memory as a function of the examination request. Here the multi-echo sequence includes variation gradients that are designed for variation of a phase encoding and/or slice encoding of a number of temporally successive echoes of an echo train resulting from the multi-echo readout. When this preferred embodiment of the method is performed, the multi-echo sequence to be applied (according to the disclosure) is already available in a data memory, preferably together with further multi-echo sequences (according to the disclosure).

Application of the multi-echo sequence provided in order to control a magnetic resonance tomography system.

The following preferred method has as its goal the dynamic generation of a multi-echo sequence (according to the disclosure) and comprises the following additional steps:

Provision of an examination request in the context of a multi-echo imaging method. Reference is made in this context to the explanations of the examination request provided above.

Production or provision of a preliminary multi-echo sequence as a function of the examination request. The preliminary multi-echo sequence can also be contained directly in the examination request, or data about the workflow of this multi-echo sequence.

Modification of the multi-echo sequence by the insertion of variation gradients that are designed for variation of a phase encoding and/or slice encoding of a number of temporally successive echoes of an echo train resulting from the multi-echo readout. In this step, therefore, a multi-echo sequence according to the disclosure is generated dynamically from a preliminary multi-echo sequence, e.g. from a MEDIC multi-echo sequence.

Application of the modified multi-echo sequence in order to control a magnetic resonance tomography system.

According to the explanations above, a multi-echo sequence that is designed to perform the method according to the disclosure can therefore be generated dynamically by producing a multi-echo sequence according to the disclosure, but can also be hard-wire preprogrammed and corresponding control commands for a magnetic resonance tomography system called up from a data memory in the event of a certain scan.

According to a preferred embodiment, after an examination request has been provided, a check is performed to determine whether a suitable multi-echo sequence according to the disclosure is present in a data memory. If the result of the check is positive, this multi-echo sequence is used; if the result of the check is negative, a multi-echo sequence according to the disclosure is produced dynamically as described above.

In a preferred method for dynamically producing a multi-echo sequence according to the disclosure, a sampling mask comprising a number of variation gradients is determined in the context of the modification. Here, for this purpose an application time and/or an amplitude and/or a temporal length of the variation gradients is determined preferably by means of random generators. This random determination is based particularly preferably on Poisson disk distributions.

In other words, the variation gradients are combined here in the form of a sampling mask. In the random determination of their application time and/or amplitude and/or temporal length, in principle the moment of the variation gradients is varied. In the subsequent application of the modified multi-echo sequence, this random production of variation gradients produces random distributions of k-space masks when different echoes are considered.

In a preferred method, a different variation in each case of the phase encoding and/or slice encoding of a number of temporally successive echoes is performed. In this case, temporally successive variation gradients preferably have different moments. These different moments can be generated randomly, for example, in the dynamic production as explained above. However, the explanations above regarding the production of the sampling mask can also be applied in the production of a multi-echo sequence that is subsequently stored in a data memory for later use.

For the single echoes, it is particularly advantageous to use k-space masks (sampling patterns) that differ from one another. One advantage here is the increased sparsity over the TE dimension. The data recorded can be regarded as 3D volumes with the echoes in the 3rd or 4th dimension and integrated in the iterative reconstruction, which enables a further increase in the undersampling.

However, the k-space masks can also be identical over the single echoes. One advantage here would be the reduced complexity in mask computation. In this preferred context a number of variation gradients can be identical.

In a preferred method, each echo is recorded with a different phase encoding and/or slice encoding.

Single images with a different TE time are preferably first reconstructed by means of iterative reconstruction in each case from the single echoes. Next, these are used particularly preferably as input for an image computation, in particular, preferably for a MEDIC image computation.

In a preferred method, the multi-echo sequence is a multi-echo sequence in the context of a MEDIC scan, a DESS scan, or a scan in the context of a DIXON method.

In a preferred multi-echo sequence, temporally successive variation gradients have different moments.

So in order to produce an image, after an excitation pulse, multiple echoes are scanned with a different echo time. The data is combined at the end to form an image. A separate sampling mask is specified for each echo. However, the number of points in each sampling mask is typically the same. The data recorded can be regarded as 3D volumes with the echoes in the third or fourth dimension (time) and integrated in an iterative reconstruction of images, which enables a further increase in the undersampling.

### BRIEF DESCRIPTION OF THE FIGURES

The disclosure is described again below in greater detail using exemplary embodiments and with reference to the accompanying figures. In the various figures, the same components are identified with identical reference signs. In the drawings:

FIG. 1 shows a schematic representation of a magnetic resonance tomography system according to an exemplary embodiment of the disclosure,

FIG. 2 shows a block diagram of the workflow of the method according to the disclosure,

FIG. 3 shows an echo train of a conventional MEDIC sequence according to convention,

FIG. 4 shows an echo train of an embodiment of a multi-echo sequence according to the disclosure, and

FIG. 5 shows a schematic diagram of k-space distributions for echoes according to one embodiment of a multi-echo sequence according to the disclosure.

In the figures only elements that are essential to the disclosure or are helpful for an understanding of it are shown.

### DETAILED DESCRIPTION

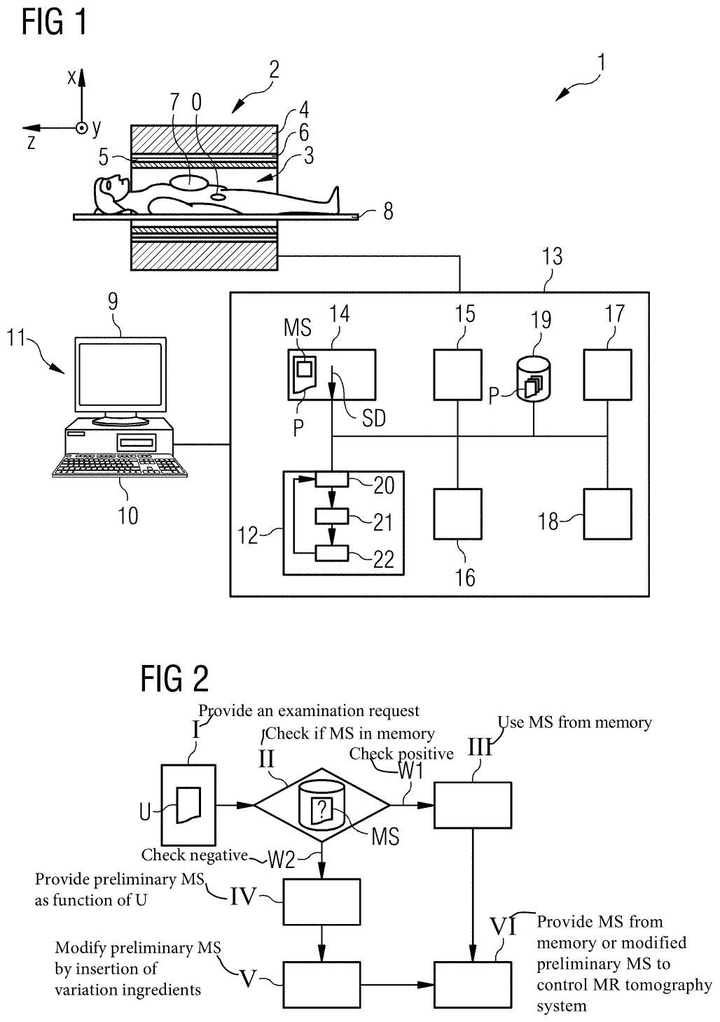

Shown in FIG. 1 in a rough schematic form is a magnetic resonance tomography system 1. It comprises, firstly, the actual magnetic resonance scanner 2 with an examination space 3 or patient tunnel in which a patient or test subject is positioned on a table 8 in whose body the actual examination object O is situated.

The magnetic resonance scanner 2 is typically equipped with a main field magnet system 4, a gradient system 6 and an HF transmitting antenna system 5 and an HF receiving antenna system 7. In the exemplary embodiment shown, the HF transmitting antenna system 5 is a whole-body coil permanently installed in the magnetic resonance scanner 2, whereas the HF receiving antenna system 7 consists of local coils to be arranged on the patient or test subject (in FIG. 1 only symbolized by a single local coil). Fundamentally, however, the whole-body coil can also be used as an HF receiving antenna system and the local coils can be used as the HF transmitting antenna system, provided these coils are each switchable into different operating modes. The main field magnet system 4 is typically configured herein so that it generates a main magnetic field in the longitudinal direction of the patient, i.e. along the longitudinal axis of the magnetic resonance scanner 2, extending in the z direction. The gradient system 6 typically comprises individually controllable gradient coils in order to be able to switch gradients in the x, y or z directions independently of one another.

The magnetic resonance tomography system shown in FIG. 1 is a whole-body system with a patient tunnel into which a patient can be completely introduced. In principle, however, the disclosure can also be used with other magnetic resonance tomography systems, e.g. with laterally open, C-shaped housings. What is essential is only that suitable images of the examination object O can be prepared.

The magnetic resonance tomography system 1 further has a central control device 13 which is used for controlling the MR system 1. This central control device 13 comprises a sequence control unit 14. With this the sequence of high-frequency pulses (HF pulses) and of gradient pulses can be controlled as a function of a selected pulse sequence, in the case of the disclosure a multi-echo sequence ES, or a sequence of several pulse sequences for imaging several slices in a volume region of interest of the examination object within one scan session. A multi-echo sequence ES can be pre-defined and parameterized for example within a scan or control protocol P. Typically, different control protocols P are stored for different scans or scan sessions in a memory 19 and can be selected by an operator (and if needed, possibly changed) and then used for carrying out the scan. In the present case, the control device 13 includes multi-echo sequences ES for the acquisition of the raw data.

For the output of the individual HF pulses of a pulse sequence, the central control device 13 has a high frequency transmitting device 15 which generates the HF pulses, amplifies and feeds them via a suitable interface (not shown in detail) into the HF transmitting antenna system 5. For the control of the gradient coils of the gradient system 6 in order to switch the gradient pulses according to the pre-defined multi-echo sequence ES accordingly, the control device 13 has a gradient system interface 16. Each of the gradients could be applied by means of this gradient system interface 16. The sequence control unit 14 communicates in a suitable manner, for example, by transmitting sequence control data SD with the high frequency transmitting device 15 and the gradient system interface 16 for carrying out the multi-echo sequence ES.

The control device 13 also has a high frequency receiving device 17 (also communicating in a suitable manner with the sequence control unit 14), in order to receive magnetic resonance signals within the readout window pre-determined by the pulse sequence in a coordinated manner by means of the HF receiving antenna system 7 and so to acquire the raw data.

Here, a reconstruction unit 18 accepts the acquired raw data and reconstructs therefrom magnetic resonance image data. This reconstruction too generally takes place on the basis of parameters which can be pre-defined in the respective scan or control protocol P. This image data can be stored, for example, in a memory 19.

How in detail, by means of an irradiation of HF pulses and the switching of gradient pulses, suitable raw data can be acquired and therefrom MR images or parameter maps can be reconstructed, is essentially known to a person skilled in the art and will therefore not be described in detail here.

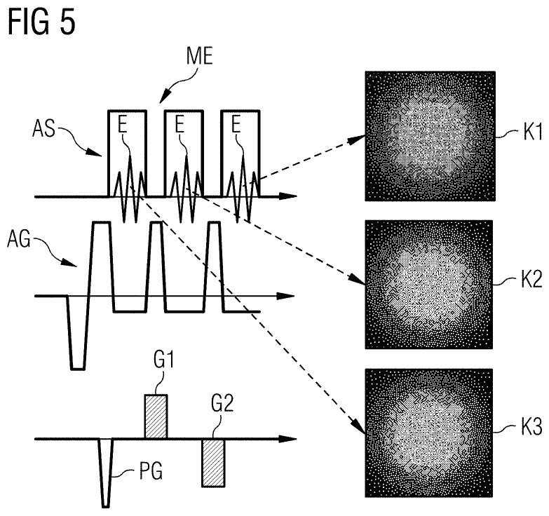

The apparatus 12 is in data communication with the other units, in particular the gradient system interface 16 or the sequence control unit 14. Alternatively, it can also be part of the sequence control unit 14. The apparatus 12 comprises multiple units. This is a data interface 20 that is designed for receiving an examination request U in the context of a multi-echo imaging method. In the example shown here, in addition to transmitting the modified multi-echo sequence MS (e.g. to the gradient system interface) this data interface 20 is designed such that this multi-echo sequence MS can be used to control a magnetic resonance tomography system 1. The apparatus 12 also comprises a production unit 21 that is designed for production or provision of a preliminary multi-echo sequence vMS as a function of the examination request U. The apparatus further comprises a modification unit 22 that is designed for modification of the preliminary multi-echo sequence vMS by the insertion of variation gradients VG. These variation gradients VG are designed here for variation of a phase encoding and/or slice encoding of a number of temporally successive echoes E (see FIG. 4) of an echo train resulting from the multi-echo readout.

Operation of the central control device 13 can take place via a terminal 11 with an input unit 10 and a display unit 9, by means of which the whole magnetic resonance tomography system 1 can thus also be operated by an operating person. Magnetic resonance tomography images can also be displayed on the display unit 9, and by means of the input unit 10, if appropriate in combination with the display unit 9, scans can be planned and initiated and in particular control protocols P can be selected and if appropriate modified.

The magnetic resonance tomography system 1 according to the disclosure and, in particular, the control device 13 can also have a plurality of further components which are not disclosed in detail here, but are typically present on such systems, such as, for example, a network interface in order to connect the overall system to a network and to be able to exchange raw data and/or image data or parameter maps, but also further data such as patient-relevant data or control protocols.

How, by means of an irradiation of HF pulses and the creation of gradient fields, suitable raw data can be acquired and therefrom magnetic resonance tomography images can be reconstructed, is essentially known to a person skilled in the art and will therefore not be described in detail here. Similarly, the most varied of scan sequences, for example, EPI scan sequences or other scan sequences for generating diffusion-weighted images are also known in principle to persons skilled in the art.

FIG. 2 shows a block diagram of the workflow of the method according to the disclosure for controlling a magnetic resonance tomography system 1 (see FIG. 1) in the context of a multi-echo imaging method. Here, the block diagram illustrates method steps.

Provision of an examination request U in the context of a multi-echo imaging method takes place in step I.

In step II, a check is performed to determine whether a suitable multi-echo sequence MS according to the disclosure is present in a data memory 19 (see FIG. 1). If the result of the check is positive W1, the process continues to step III and this multi-echo sequence MS is used; if the result of the check is negative W2, the process continues to steps IV and V and a multi-echo sequence MS according to the disclosure is produced dynamically.

In step III, a multi-echo sequence MS from the data memory 19 is provided as a function of the examination request U, wherein this multi-echo sequence MS includes variation gradients G1, G2, G3, G4, G5, G6 that are designed for variation of a phase encoding and/or slice encoding of a number of temporally successive echoes E of an echo train resulting from the multi-echo readout (see FIG. 4).

In step IV, a preliminary multi-echo sequence vMS is produced or provided as a function of the examination request U.

In step V, the preliminary multi-echo sequence vMS is modified by the insertion of variation gradients G1, G2, G3, G4, G5, G6.

In step VI, the multi-echo sequence MS provided from the data memory or modified is applied in order to control a magnetic resonance tomography system 1.

In the context of the application of the multi-echo sequence MS according to the disclosure, an excitation of a multi-echo readout occurs in the context of the multi-echo imaging method together with a variation of a phase encoding and/or slice encoding of a number of temporally successive echoes E of an echo train resulting from the multi-echo readout.

Highly simplified diagrams are used below to depict multi-echo sequences ES. For a better understanding of the disclosure, the various pulses are shown as a function of time t on a single time base. Usually, HF pulses are shown on a high frequency-pulse time axis, and gradient pulses are shown on three gradient-pulse time axes, which correspond to three spatial directions. The gradient pulses represented below can therefore be oriented in space as required. Because only a representation of the echo trains of the multi-echo sequences MS is of interest in order to understand the disclosure, the HF pulses are not represented below.

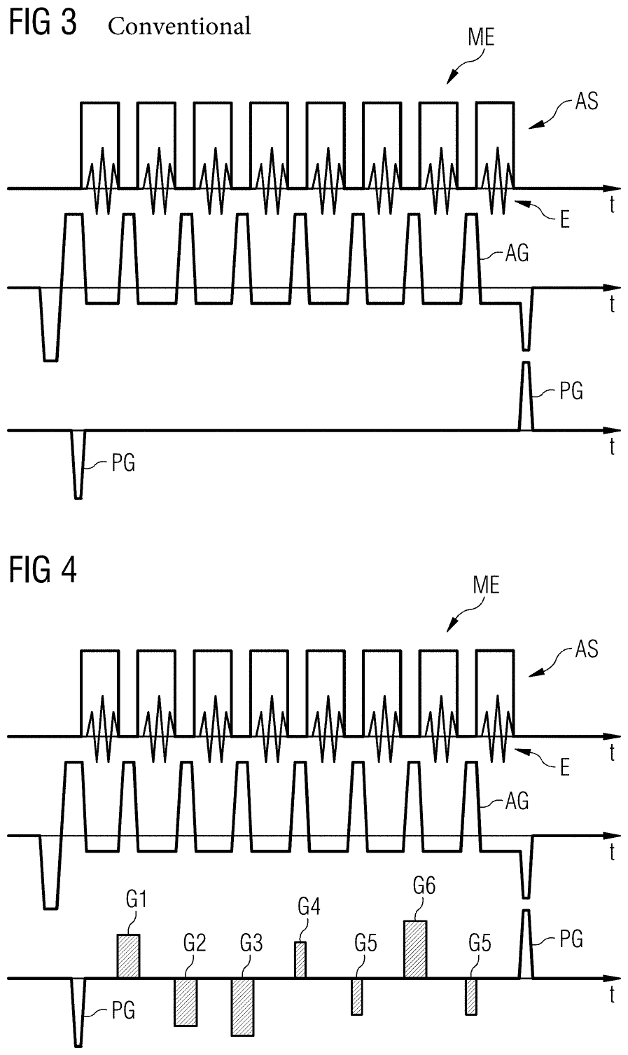

FIG. 3 shows an echo train of a conventional MEDIC sequence MS according to convention, which serves here as an example of a multi-echo sequence MS. The arrows symbolize time axes t. Shown on the top time axis t is an ADC signal AS, which opens readout windows for recording the echoes E and thus allows the recording of signals. Shown on the central time axis t is a readout signal with multiple readout gradients AG. These readout gradients AG are applied, by way of example, between the pulses of the ADC signal AS on the x gradient axis of the magnetic resonance tomography system 1 (see FIG. 1). Shown on the bottom time axis t, which can be the y gradient axis for example, are two phase encoding gradients PG, one at the start and one at the end of the readout.

In FIG. 4 this multi-echo sequence MS is shown in the form of an example of an embodiment according to the disclosure. On the bottom time axis t additional gradients, the variation gradients G1, G2, G3, G4, G5, G6, have been inserted between the two phase encoding gradients PG, which produce a variation of the phase encoding of the subsequent echoes E of the echo train resulting from this multi-echo sequence MS.

The additional variation gradients G1, G2, G3, G4, G5, G6 are shaded for clarity. In contrast to the conventional MEDIC imaging according to FIG. 1, with this multi-echo sequence MS every echo E is recorded with a different phase encoding. In each case a varying sequence in the processing of the sampling patterns is produced, i.e. for the single echo times, adjacent k-space coordinates are not necessarily sampled in real time in relation to echo times that are adjacent.

For the single echoes E, it is particularly advantageous to use k-space masks (sampling patterns) that differ from one another for the scans. One advantage then is the increased sparsity over the TE dimension. This can be achieved with a method according to the disclosure or a multi-echo sequence MS according to the disclosure.

FIG. 5 shows an example assignment of the sampling patterns, i.e. the k-space masks K1, K2, K3, for the start of the echo train of the multi-echo sequence MS according to FIG. 4. Although it may not be visible easily to the naked eye, in this case each echo E has a different distribution of the k-space positions to be sampled. The top k-space mask K1 is applied for the first echo E, the central k-space mask K2 is applied for the second echo E, which occurs after the first variation gradient G1, and the bottom k-space mask K3 is applied for the third echo E, which occurs after the second variation gradient G2.

As a result of this imaging, the sequence in the processing of the sampling patterns is different. This means that k-space coordinates for the single echo times are not necessarily sampled in real time in relation to echo times that are adjacent. It can be seen from the three images that analyzing the three different k-space masks K1, K2, K3 in succession means that the k-space coordinates change constantly. In broad summary, it could be said that constantly changing the point pattern results in an analysis with irregularly changing coordinate distributions. As a result, motion artifacts manifest less as specific ghosts (as in classical imaging with Grappa) and instead are merely spread across the image. These effects can then be suppressed in turn by means of regularization in the iterative reconstruction.

Single images with a different TE time can be first reconstructed by means of iterative reconstruction in each case from the single echoes E. These can be used as input for an image computation, e.g. in the context of a MEDIC method for the MEDIC image computation.

The principle of the disclosure has been shown for the MEDIC sequence as an example. Similarly, it can also be used in other multi-echo methods, in particular in DESS or DIXON imaging.

Finally, it should be reiterated that the method described in detail above and the presented apparatuses are merely exemplary embodiments, which can be modified by a person skilled in the art in many ways without departing from the scope of the disclosure. In addition, the use of the indefinite article “a” or “an” does not rule out the possibility of there also being more than one of the features concerned. Likewise, the terms “unit” and “module” do not exclude the possibility that the components in question consist of a plurality of interacting sub-components, which may also be spatially distributed if applicable.

1. A method for controlling a magnetic resonance tomography system in a context of a multi-echo imaging method, comprising:
exciting a multi-echo readout in the context of the multi-echo imaging method; and
varying a phase encoding or slice encoding of temporally successive echoes of an echo train resulting from the multi-echo readout.

2. The method as claimed in claim 1, further comprising:
providing an examination request in the context of the multi-echo imaging method;
providing a multi-echo sequence from a data memory as a function of the examination request, wherein the multi-echo sequence is modified to include variation gradients that are designed for variation of a phase encoding or slice encoding of temporally successive echoes of an echo train resulting from the multi-echo readout; and
applying the modified multi-echo sequence in order to control a magnetic resonance tomography system.

3. The method as claimed in claim 1, further comprising:
providing an examination request in the context of the multi-echo imaging method;
producing or providing a preliminary multi-echo sequence as a function of the examination request;
modifying the preliminary multi-echo sequence by inserting variation gradients that are designed for variation of a phase encoding or slice encoding of temporally successive echoes of an echo train resulting from the multi-echo readout;
applying the modified multi-echo sequence to control the magnetic resonance tomography system;
after providing the examination request, checking whether a suitable multi-echo sequence is present in a data memory;
if the result of the checking is positive, using the multi-echo sequence from the data memory; and
if the result of the checking is negative, using the modified preliminary multi-echo sequence.

4. The method as claimed in claim 3, further comprising:
determining a sampling mask comprising variation gradients in context of the modifying, and for this purpose, determining an application time, an amplitude, or a temporal length of the variation gradients using random generators based on Poisson disk distributions.

5. The method as claimed in claim 1, further comprising:
performing a different variation in each case of the phase encoding or slice encoding of temporally successive echoes, wherein temporally successive variation gradients have different moments.

6. The method as claimed in claim 1, wherein each echo is recorded with a different phase encoding or slice encoding.

7. The method as claimed in claim 1, further comprising:
reconstructing single images with a different TE time using iterative reconstruction in each case from single echoes; and
inputting the reconstructed single images for a Multi-Echo Data Image Combination (MEDIC) image computation.

8. The method as claimed in claim 1, wherein the multi-echo sequence is a multi-echo sequence in context of a Multi-Echo Data Image Combination (MEDIC) scan, a Dual-Echo Steady-State (DESS) scan, or a scan in context of a DIXON method.

9. An apparatus for generating a multi-echo sequence, comprising:
a data interface configured to receive an examination request in context of a multi-echo imaging method;
a producer configured to produce or provide a preliminary multi-echo sequence as a function of the examination request;
a modifier configured to modify the preliminary multi-echo sequence by inserting variation gradients that are designed for variation of a phase encoding or slice encoding of temporally successive echoes of an echo train resulting upon application of the multi-echo sequence; and
a data interface configured to transmit the modified multi-echo sequence to be used to control a magnetic resonance tomography system.

10. A controller configured to control the magnetic resonance tomography system by performing the method as claimed in claim 1.

11. The magnetic resonance tomography system comprising the controller as claimed in claim 10.

12. A non-transitory computer program product comprising a computer program which is loadable directly into a memory of a processing system or of a controller of a medical resonance tomography system, and which comprises program segments, in order to perform the steps of the method as claimed in claim 1 when the computer program is executed in the processing system or the controller.

13. A non-transitory computer-readable medium on which program portions are readable and executable by a computer are stored, in order to carry out the steps of the method as claimed in claim 1 when the program portions are executed by the computer.
